(19) United States
(12) Patent Application Publication
(10) Pub. No.: US 2013/0005063 A1
(43) Pub. Date: Jan. 3, 2013

(54) SUBSTRATE TREATING DEVICE USING PLASMA AND MANUFACTURING METHOD OF ORGANIC LIGHT EMITTING DIODE DISPLAY USING THE SUBSTRATE TREATING DEVICE

(76) Inventor: Jae-Ho YANG, Yongin-City (KR)

(21) Appl. No.: 13/301,065

(22) Filed: Nov. 21, 2011

(30) Foreign Application Priority Data
Jun. 30, 2011 (KR) 10-2011-0065019

(51) Int. Cl. H01L 33/08; C23C 16/00; B08B 5/00

(52) U.S. Cl. 438/34; 156/345.38; 118/723 R; 257/E33.055

(57) ABSTRACT

A substrate treatment device includes a substrate processing chamber where a plasma treatment process is performed, a rib structure provided in an upper portion of the substrate processing chamber, the rib structure having a form of a three-dimensional structure bent along at least one direction, dielectric material structures, each having an edge fixed to the rib structure; and an antenna provided in a portion of each of dielectric materials facing an exterior of the substrate treatment device, the antenna being connected with a high frequency power source and forming an inductive electromagnetic field in the substrate processing chamber.

### RELATED APPLICATIONS

This application claims priority to and the benefit of Korean Patent Application No. 10-2011-0065019 filed in the Korean Intellectual Property Office on Jun. 30, 2011, the entire contents of which are incorporated herein by reference.

### BACKGROUND

1. Field

Embodiments of the described technology relate generally to a substrate treatment device using plasma. More particularly, embodiments relate generally to a large-sized substrate treatment device using inductively coupled plasma and a manufacturing method of an organic light emitting diode (OLED) display using the same.

2. Description of the Related Art

In general, the term “plasma” may refer to an ionized gas state formed of ions, electrons, radicals, and the like, and is generated by a strong electric field or radio frequency (RF) electromagnetic fields. A substrate treatment device is a device performing treatment such as etching, deposition, or ashing using the plasma. The substrate treatment device is classified into a capacitively coupled plasma treatment device, an inductively coupled plasma treatment device, and a microwave plasma treatment device according to a plasma generation energy source.

The above information disclosed in this Background section is only for enhancement of understanding of the background of the described technology and therefore it may contain information that does not form the prior art that is already known in this country to a person of ordinary skill in the art.

### SUMMARY

According to an embodiment, there is provided a substrate treatment device including a substrate processing chamber where a plasma treatment process is performed, a rib structure provided in an upper portion of the substrate processing chamber, the rib structure having a form of a three-dimensional structure bent along at least one direction, dielectric material structures, each having an edge fixed to the rib structure, and an antenna provided in a portion of each of dielectric materials facing an exterior of the substrate treatment device, the antenna being connected with a high frequency power source and forming an inductive electromagnetic field in the substrate processing chamber through an inner space of each of the dielectric material structures.

The rib structure may include first structures extending downwardly in a radial manner from a center apex and second structures disposed along a circumferential direction so as to cross the first structures.

The first structures may be equidistantly spaced apart at a lowest end of the rib structure, contacting the substrate processing chamber.

The second structures may be individually dimensioned according to a distance and curvature between respective first structures. Ends of the second structures may be coupled to the first structures.

The first structures and the second structures may each include base supports forming a basic frame and protrusion portions formed at a center of an external surface of the base support. The external surface of the base support and a side surface of the protrusion portion may form a seating portion that supports an edge of one of the dielectric material structures.

The rib structure may include third structures disposed in parallel with each other at a distance from each other and bent along one direction, and fourth structures disposed along a circumference direction so as to cross the third structures.

The third structures may be bent to the same direction, and one of the third structures disposed in the middle of the third structures may have the greatest height.

The fourth structures may be individually dimensioned according to a distance and curvature between the third structures. Ends of the fourth structure may be coupled to the third structures.

The third structures and the fourth structures may each include base supports forming a basic frame and protrusion portions formed in a center of an external surface of the base support. The external surface of the base support and a side surface of the protrusion portion may form a seating portion that supports an edge of one of the dielectric material structures.

The rib structure may further include a center structure bent along a direction crossing the third structures.

The rib structure may further include fifth structures disposed in parallel with each other at a distance from each other and bent along one direction, and sixth structures disposed in a straight line and crossing the fifth structures.

The fifth structures may be bent to the same direction and have the same length. The sixth structures may be separated from each other by a same distance along a length direction of the fifth structures.

The sixth structures may be individually dimensioned with a length corresponding to the distance between the fifth structures. Ends of the sixth structure may be coupled to the fifth structures.

The fifth structures and the sixth structures may each include base supports forming a basic frame and protrusion portions formed in a center of an external surface of the base support. The external surface of the base support and a side surface of the protrusion portion may form a seating portion supporting an edge of one of the dielectric material structures.

The dielectric material structures may each be dimensioned to correspond to a size and curvature of a space partitioned by the rib structure.

A gas inlet for injection of a reaction gas may be disposed in one of the dielectric material structures.

According to an embodiment, there is provided a manufacturing method of an organic light emitting diode (OLED) display, the method including forming a driving circuit including a thin film transistor and a capacitor, and forming an organic light emitting element electrically connected with the driving circuit, wherein in at least one of the forming of the driving circuit and the forming of the organic light emitting element, at least one of deposition, etching, and ashing is performed using the substrate treatment device.

### BRIEF DESCRIPTION OF THE DRAWINGS

FIG. 1 is a perspective view of a substrate treatment device according to an exemplary embodiment.

FIG. 2 is a cross-sectional view of the substrate treatment device of FIG. 1.

FIG. 3 is a perspective view of a rub structure in the substrate treatment device of FIG. 1.

FIG. 4 is a cross-sectional view of the rib structure of FIG. 3, taken along the line I-I.

FIG. 5 is a perspective view of the rib structure and a dielectric material of FIG. 1.

FIG. 6 is a cross-sectional view of the rib structure of FIG. 5, taken along the line II-II.

FIG. 7 is a schematic diagram of a connection state of antennas of FIG. 1.

FIG. 8 is a perspective view of a substrate treatment device according to another exemplary embodiment.

FIG. 9 is a perspective view of a rib structure in the substrate treatment device of FIG. 8.

FIG. 10 is a perspective view of a substrate treatment device according to another exemplary embodiment.

FIG. 11 is a perspective view of a rib structure in the substrate treatment device of FIG. 10.

FIG. 12 is a layout view of an organic light emitting diode (OLED) display according to another exemplary embodiment.

FIG. 13 is a cross-sectional view of FIG. 12, taken along the line A-A.

### DETAILED DESCRIPTION

Embodiments will be described more fully hereinafter with reference to the accompanying drawings, in which exemplary embodiments of the invention are shown. As those skilled in the art would realize, the described embodiments may be modified in various different ways, all without departing from the spirit or scope embodiment.

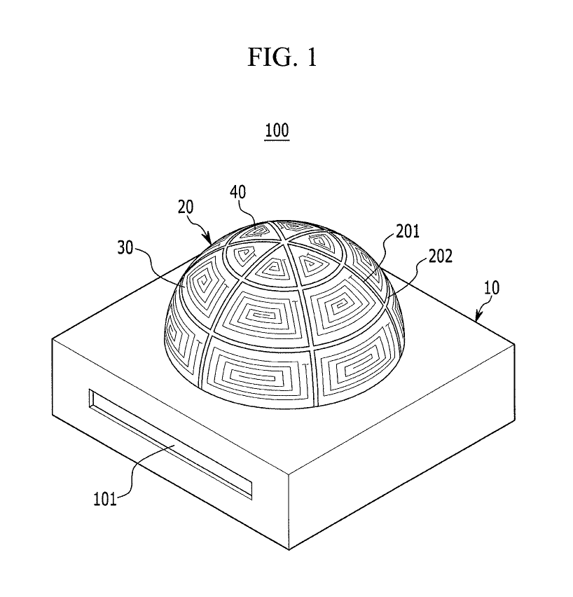

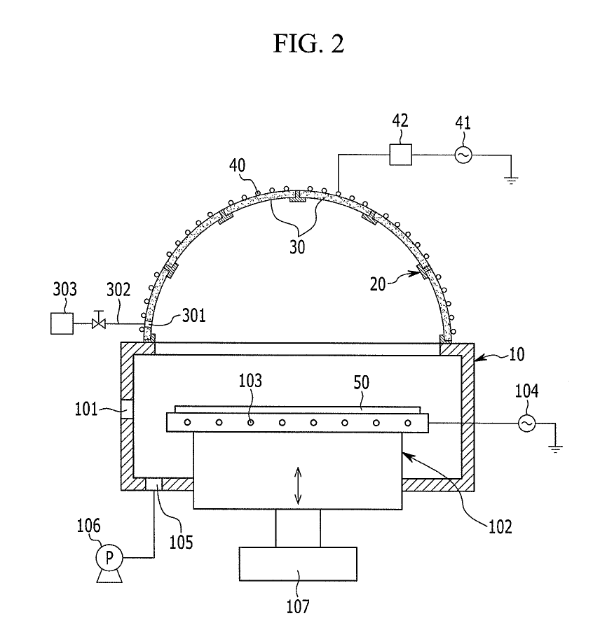

FIG. 1 is a perspective view of a substrate treatment device according to an embodiment, and FIG. 2 is a cross-sectional view of the substrate treatment device of FIG. 1.

Referring to FIG. 1 and FIG. 2, a substrate treatment device 100 according to this embodiment may include a substrate processing chamber 10, a rib structure 20, a plurality of dielectric material structures 30, and a plurality of antennas 40. The substrate treatment device 100 may form an inductive electromagnetic field in the substrate processing chamber 10, and may perform substrate treatment such as deposition, etching, and ashing using plasma generated from the inductive electromagnetic field.

The substrate processing chamber 10 may provide a space for substrate treatment process using the plasma. The substrate processing chamber 10 may be substantially formed in the shape of a cuboid, and an opening 101 may be formed at a side wall of the substrate processing chamber 10 to enable carrying in and out of a substrate. The opening 101 may be selectively opened or closed by a door member (not shown).

A substrate support 102 supporting a substrate 50 may be formed in the substrate processing chamber 10. As the substrate support 102, an electrostatic chuck may adsorbably support a substrate with electrostatic force or a vacuum chuck may adsorbably support a substrate with a vacuum force. Alternatively, the substrate support 102 may support a substrate using a mechanical clamping method.

The substrate support 102 may be provided to be movable up and down by a driving member 107. Thus, the substrate 50 may be disposed in an area having uniform plasma density distribution. A heating member 103 that can heat the substrate 50 to a process temperature may be provided in the substrate support 102. As the heating member 103, a resistive heat generator such as a coil may be used.

The substrate support 102 may be connected with a high-frequency power source 104, and an adapter (not shown) may be disposed between the substrate support 102 and the high-frequency power source 104. The high-frequency power source 104 may provide a bias voltage to the substrate support 102 to make ions and radicals of the plasma generated in the inner space of the rib structure 20 and the dielectric material structures 30 collide with sufficiently high energy against the surface of the substrate 50.

The substrate processing chamber 10 may be connected with an exhaust hole 105 through the vacuum pump 106. The vacuum pump 106 may maintain the substrate processing chamber 10 in a vacuum state by exhausting the same. A pressure control value (not shown) may be provided on an exhaust line connecting the exhaust hole 105 and the vacuum pump 106.

The substrate processing chamber 10 may form an inner space that is proportional to the size of the substrate 50 for treatment of large-sized substrate for display. In addition, a structure for generating inductively coupled plasma, that is, the rib structure 20 for supporting the dielectric material structures 30 and the antenna 40 may also be formed in proportional to the size of the substrate 50. In this case, the rib structure 20 and the dielectric material structures 30 may be formed as a three-dimensional structure bent along at least one direction.

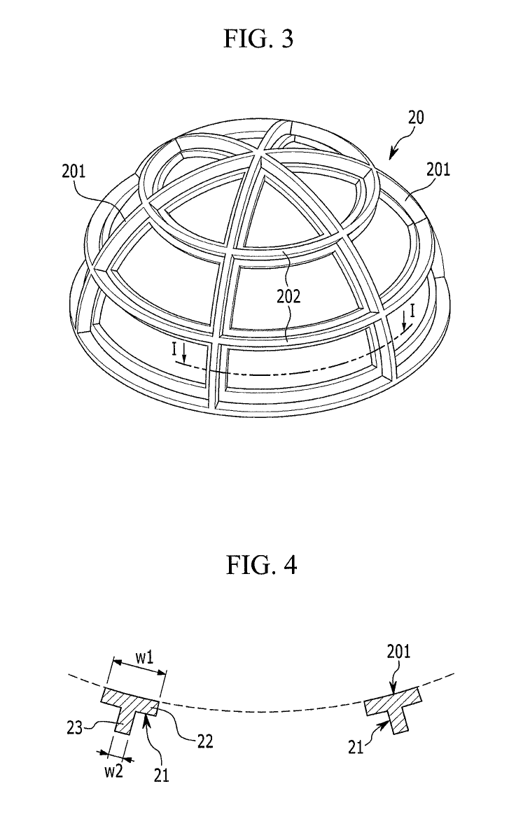

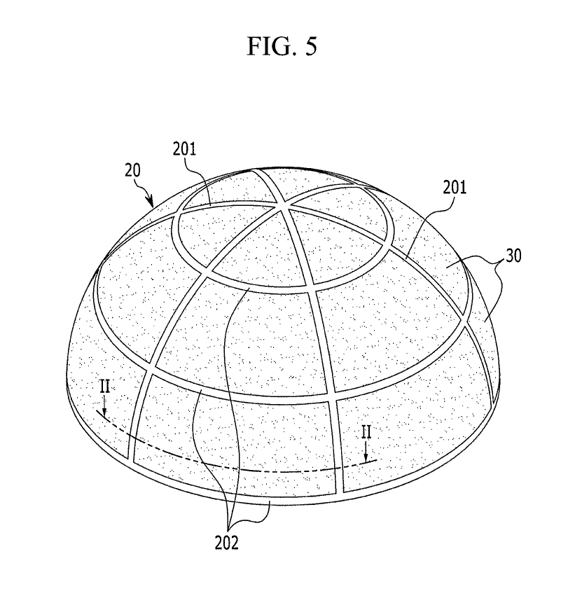

FIG. 3 is a perspective view of the rib structure in the substrate treatment device of FIG. 1 and FIG. 4 is a cross-sectional view of the rib structure of FIG. 3, taken along the line I-I.

Referring to FIG. 3 and FIG. 4, the entire frame of the rib structure 20 may be formed in the shape of a dome. The rib structure 20 may include a plurality of first structures 201 extended in a radial manner from a center apex at the uppermost end thereof to downward and a plurality of second structures 202 arranged along a circumference direction so as to cross the first structures 201.

The rib structure 20 may be formed of a metal such as aluminum or stainless steel. The plurality of first structures 201 may respectively have the same distance at the lowest end of the rib structure 20, contacting the substrate processing chamber 10. In addition, distances of the second structures 202 measured along a length direction of the first structures 201 may be equivalent or different from each other.

The second structures 202 may be individually dimensioned with a length corresponding to each distance of the first structures 201. In this case, each second structure 202 may be disposed between two neighboring first structures 201, and both ends of the second structure 202 may be fixed to the first structures 201 through a mechanical coupling method such as welding or bolt-nut coupling. For convenience, FIG. 3 exemplarily illustrates that the first structure 201 and the second structure 202 are integrally connected.

The rib structure 20 may be a support for supporting the dielectric material structures 30, and therefore the rib structure 20 may include a seating portion 21 to fix the edges of the dielectric material structures 30. Thus, each of the first and second structures 201 and 202 may have a “T” shaped cross-section.

In further detail, each of the first structure 201 and the second structure 202 may include a base support 22 and a protrusion portion 23 formed at a center of an external surface of the base support 22. Referring to FIG. 4, a width w1 of the base support 22 may be larger than a width 2 of the protrusion portion 23, and therefore the external surface of the base support 22 and a side surface of the protruding portion 23 may function as the seating portion 21 for seating the edges of the dielectric material structures 30.

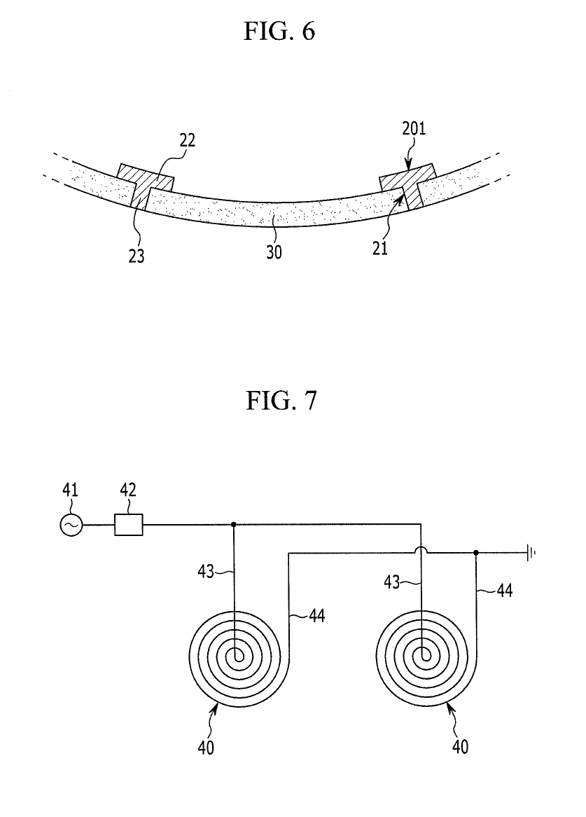

FIG. 5 is a perspective view of the rib structure and the dielectric material structures in the substrate treatment device of FIG. 1, and FIG. 6 is a cross-sectional view of the rib structure of FIG. 5, taken along the line II-II.

Referring to FIG. 5 and FIG. 6, a single dielectric material structure 30 may be independently arranged in each space partitioned by the first structure 201 and the second structure 202. Each dielectric material structure 30 may be individually dimensioned according to the size and curvature of the space partitioned by the first structure 201 and the second structure 202 and then fixed to the seating unit 21 of the rib structure 20. The dielectric material structure 30 may have a constant thickness, and may be formed of quartz or ceramic.

A plurality of dielectric materials structures 30 may form a dome-shaped structure together with the rib structure 20. The dome-shaped rib structure 20 may be very stable in shape so that the rib structure 20 can stably support the dielectric materials structures 30 while maintaining the first structure 201 and the second structure 202 with a small width. When the width of the first and second structures 201 and 202 are small, most of the dome-shape structure may be formed by the dielectric material 30 structures.

Referring to FIG. 1 and FIG. 2, a gas inlet 301 for injection of a reaction gas for plasma generation may be formed in one dielectric material 30 of the plurality of dielectric materials 30. The gas inlet 301 may be connected with a gas supply line 302, and a reaction gas supply source 303 may be provided on the gas supply line 302.

The antennas 40 may be respectively disposed at upper portions of the respective dielectric material structures 30. The antenna 40 may be a spiral-shaped inductively coupled plasma antenna, and functions to transmit radio-frequency (RF) power for plasma generation from the reaction gas injected to the dome-shaped structure. The RF power may be passed through the dielectric material structures 30 and then provided to an inner space of the dome-shape structure.

FIG. 7 is a schematic diagram of a connection state of the antennas of FIG. 1.

Referring to FIG. 1 and FIG. 7, each antenna 40 may be spirally disposed in an upper portion of each dielectric material structure 30, and the plurality of antennas 40 may be connected with a high-frequency power source 41 for supplying the RF power.

For example, each antenna 40 may include a first end portion 43 connected with a center of the spiral and a second end portion 44 connected with an edge of the spiral. The first end portions 43 may be connected with each other such that they can be connected with the high-frequency power source 41. In addition, an adapter 42 may be provided between the antennas 40 and the high-frequency power source 41. A connection state of the antennas 40 can be variously modified.

When the high-frequency power source 41 is activated, the RF power of the high-frequency power source 41 may be uniformly distributed to the antennas 40. The RF power distributed to the antennas 40 forms a magnetic field in the inner space of the dome-shaped structure.

An inductive electric field may be formed due to time-based variation of the magnetic field, and a reaction gas supplied to an inner space of the dome-shaped structure acquires sufficient energy for ionization from the inductive electric field to generate plasma. The plasma may collide with the surface of the substrate 50 disposed in the substrate processing chamber 10 to process the substrate 50.

In the above-stated treatment process of the substrate 50, the dielectric material structures 30 and the rib structure 20 for plasma generation may be provided with an increased size as the size of the substrate 50 is increased. The substrate treatment device 100 of the first exemplary embodiment provides the dome-shaped structure 20 so that stability in shape can be improved while reducing the width of the rib structure 20. Thus, the rib structure 20 can stably support the dielectric material structures 30.

In addition, as the width of the rib structure 20 is reduced, the rib structure 20 experiences coupling with the electromagnetic field induced from the antenna 40 during a treatment process of the substrate 50 such that shielding of the electromagnetic field can be minimized. Thus, a power loss due to the rib structure 20 can be suppressed, thereby improving treatment efficiency of the substrate 50.

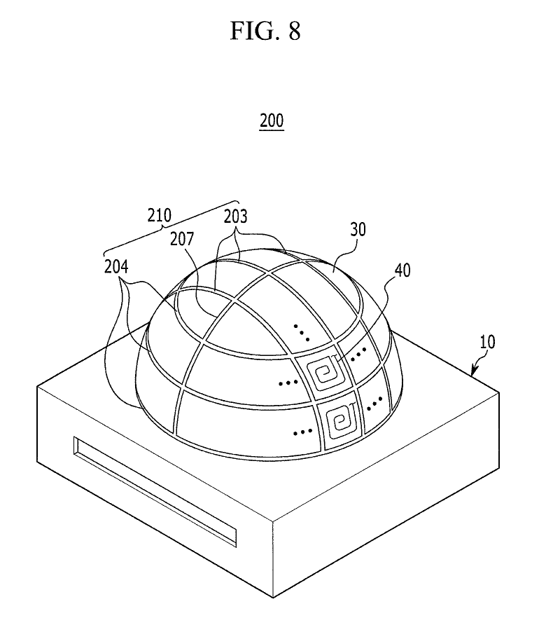

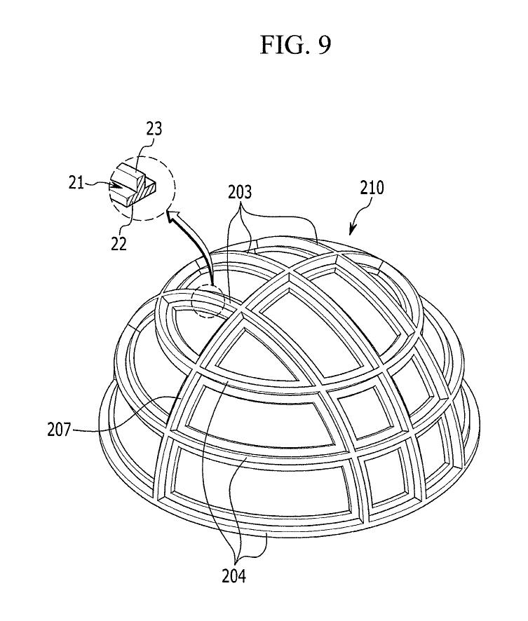

FIG. 8 is a perspective view of a substrate treatment device according to another embodiment and FIG. 9 is a perspective view of a rib structure of the substrate treatment device of FIG. 8.

Referring to FIG. 8 and FIG. 9, a substrate treatment device 200 of this embodiment has the same structure of the substrate treatment device of the embodiment of FIGS. 1 to 7, except that rib structures 210 are arranged in parallel with each other at a distance from each other and are formed of a plurality of third structures 203 bent along one direction and a plurality of fourth structures 204 disposed along a circumference direction so as to cross the plurality of third structures 203. (It is to be understood that in the embodiment of FIGS. 8 and 9, the labeling of rib structures as “third” and “fourth” structures is not meant to imply that first and second structures must also be present in this embodiment. Instead, the labeling of the rib structures as “third” and “fourth” structures serves to distinguish these structures from the rib structures of the embodiment of FIGS. 1 to 7.)

Like reference numerals designate like elements as those of the embodiment of FIGS. 1 to 7, and parts that are different will be described.

The third structures 203 may be bent to the same direction, and arranged in parallel with each other at a distance from each other. When the third structures 203 are provided in an odd-number, for example, three, the third structure 203 disposed at the center among the three structures 203 may have the highest height and the other two third structures 23 may have the same height. The fourth structures 204 may be arranged along a circumference direction and cross the third structures 203.

The fourth structures 204 may be individually dimensioned with a length corresponding to a distance of the respective third structures 203. In this case, the fourth structure 204 may be disposed between two neighboring third structures 203, and both ends of the fourth structure 204 may be fixed to the third structures 203 by a mechanical coupling method such as welding or bolt-nut coupling. For convenience, FIG. 8 and FIG. 9 exemplarily illustrate that the third structures 203 and the fourth structure 204 may be integrally connected.

A rib structure 210 may include a center structure 207 bent along a direction crossing the third structures 203. The center structure 207 may be disposed to across the uppermost end of the rib structure 210. Such a center structure 207 perpendicularly crosses the fourth structures 204. The center structure 207 may function to supplement the strength of the rib structure 210 in an area where the strength of the third structure 201 cannot reach among the rib structure 210.

As in the embodiment of FIGS. 1 to 7, the third structure 203, the fourth structure 204, and the center structure 207 respectively may include base supports 22 forming a base frame and protrusion portions 23 formed at a center of an external surface of the base support 22. The external surface of the base support 22 and a side surface of the protrusion portion 23 may function as a seating portion for fixing edges of the dielectric material structures 30.

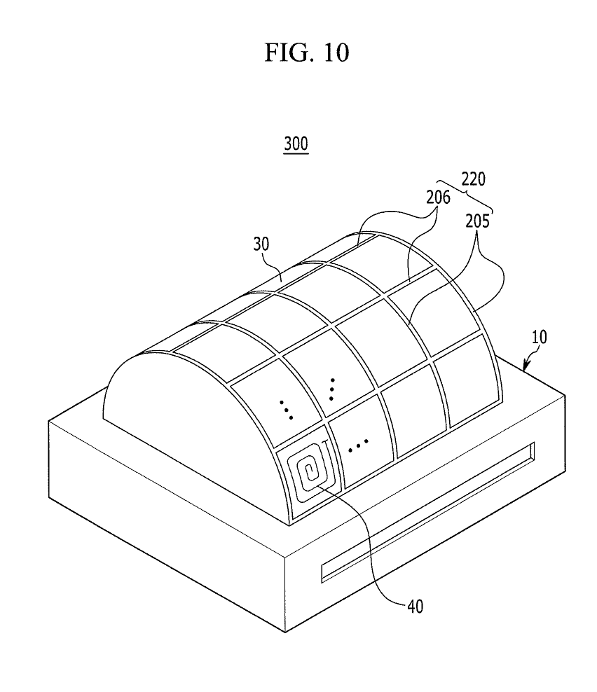

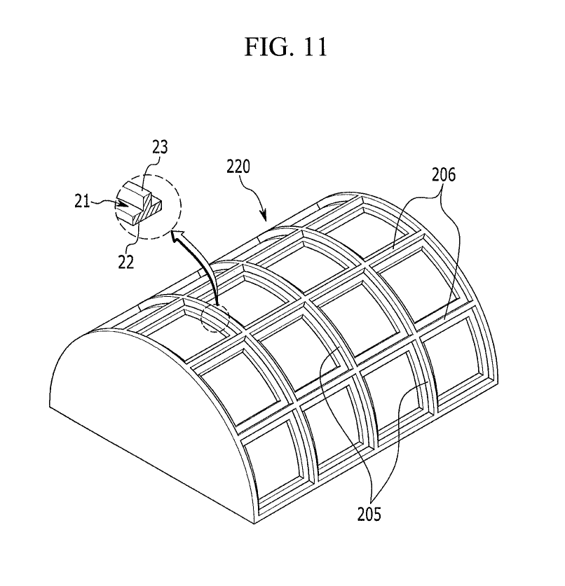

FIG. 10 is a perspective view of a substrate treatment device of according to another exemplary embodiment and FIG. 11 is a perspective view of a rib structure in the substrate treatment device of FIG. 10.

Referring to FIG. 10 and FIG. 11, a substrate treatment device 300 of this exemplary embodiment may have the same structure as the substrate treatment device of the embodiment of FIGS. 1 to 7, except that a plurality of rib structures 220 may be disposed in parallel with each other at a distance from each other and formed of a plurality of fifth structures 205 bent along one direction and a plurality of sixth structures 206 crossing the plurality of fifth structures 205. (It is to be understood that in the embodiment of FIGS. 10 and 11, the labeling of rib structures as “fifth” and “sixth” structures is not meant to imply that first, second, third and fourth structures must also be present in this embodiment. Instead, the labeling of the rib structures as “fifth” and “sixth” structures serves to distinguish these structures from the rib structures of the embodiment of FIGS. 1 to 7 and the embodiment of FIGS. 8 and 9.)

Like reference numerals designate like elements as those of the embodiment of FIGS. 1 to 7, and parts that are different will be described.

The fifth structures 205 may be bent to the same direction, and respectively may have the same length. The fifth structures 205 may be separated from each other by a same distance along one direction. The sixth structures 206 may be straight line type structures, and may be arranged to cross the fifth structures 205. The sixth structures 206 may be separated from each other by a same distance along a length direction to which the fifth structures 205 are bent. In the substrate treatment device of the third exemplary embodiment, the rib structure 220 may be formed in the shape of a greenhouse or Quonset hut.

The sixth structures 206 may be individually dimensioned with a length that corresponds to a distance between the fifth structures 205. In this case, the sixth structure 206 may be disposed between two neighboring fifth structures 205, and both ends of the sixth structure 206 may be fixed to the fifth structures 205 by a mechanical coupling method such as welding or bolt-nut coupling. For convenience, FIG. 10 and FIG. 11 exemplarily illustrate that the fifth structure 25 and the sixth structure 206 may be integrally connected.

As in the embodiment of FIGS. 1 to 7, the fifth structure 205 and the sixth structure 206 respectively may include base supports 22 forming a basic frame and protrusions 23 formed at a center of an external surface of the base support 22. The external surface of the base support 22 and a side surface of the protrusion portion 23 may function as a seating portion for fixing edges of the dielectric material supports 30. The substrate treatment device 300 of the third exemplary embodiment may have a structure that is appropriate in treatment of a substrate 50 having a large aspect ratio.

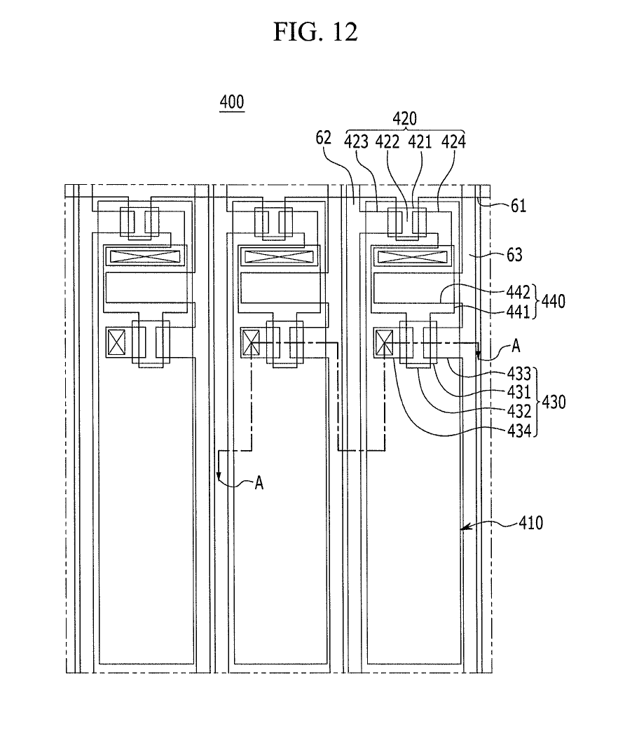

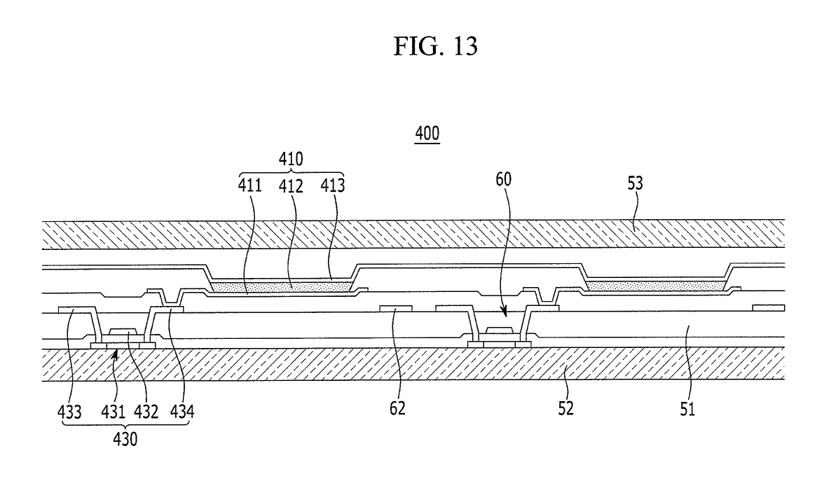

Next, a method for manufacturing an organic light emitting diode (OLED) display using the above-stated substrate treatment device will be described. FIG. 12 is a layout view of an OLED display and FIG. 13 is a cross-sectional view of FIG. 12, taken along the line A-A. A pixel structure described hereinafter is an exemplary structure, and the OLED display according to the present exemplary embodiment is not limited thereto.

Referring to FIG. 12 and FIG. 13, an OLED display 400 may include a plurality of pixels, and each pixel may include an organic light emitting element 410 and a driving circuit. The driving circuit may include at least two thin film transistors 420 and 430 and at least one capacitor 440. The thin film transistors 420 and 430 may basically include a switching transistor 420 and a driving transistor 430.

The organic light emitting element 410 may include a pixel electrode 411, an organic emission layer 412, and a common electrode 413. The pixel electrode 411 may be a hole injection electrode and the common electrode 413 may be an electron injection electrode. Holes and electrodes may be injected into the organic emission layer 412 respectively from the pixel electrode 411 and the common electrode 413. When an exciton, in which a hole and an electron injected into the organic emission layer 412 are coupled to each other, falls from an excited state to a ground state, light emission occurs.

The capacitor 440 may include a first capacitor plate 441 and a second capacitor plate 442 disposed, interposing an interlayer insulating layer 51 therebetween. The switching transistor 420 may include a switching semiconductor layer 421, a switching gate electrode 422, a switching source electrode 423, and a switching drain electrode 424. The driving transistor 430 may include a driving semiconductor layer 431, a driving gate electrode 432, a driving source electrode 433, and a driving drain electrode 434.

The switching transistor 420 may be used as a switch for selecting a pixel. The switching gate electrode 422 may be connected to a gate line 61 and the switching source electrode 423 may be connected to a data line 62. The switching drain electrode 424 may be connected to the first capacitor plate 441.

The driving transistor 430 applies a driving voltage to the pixel electrode 411 for light emission of an organic emission layer 412 of the selected pixel. The driving gate electrode 432 may be connected to the first capacitor plate 441, and the driving source electrode 433 and the second capacitor plate 442 may be connected to a power line 63. The driving drain electrode 434 may be connected to the pixel electrode 411 of the organic light emitting element 410 through a contact hole.

The switching transistor 420 may be driven by a scan voltage applied to the gate line 61 and transmits a data voltage applied to the data line 62 to the driving transistor 430. A voltage that corresponds to a difference between a common voltage applied to the driving transistor 430 from the power line 63 and the data voltage transmitted from the switching transistor 420 may be stored in the capacitor 440, and a current corresponding to the voltage stored in the capacitor 440 may flow to the organic light emitting element 410 through the driving transistor 430 such that the organic emission layer 412 emits light.

In FIG. 13, reference numeral 52 denotes a substrate and reference numeral 53 denotes an encapsulation substrate protecting the organic light emitting element 410.

The OLED display 400 may be manufactured through a process for sequentially layering several layers forming the driving circuit and the organic light emitting element 410 from the substrate 52. The manufacturing method of the OLED display 400 according to the present exemplary embodiment may include forming a driving circuit including the thin film transistors 420 and 430 and the capacitor 440 and forming the organic light emitting element 410 electrically connected with the driving circuit. When manufacturing at least one of the driving circuit and the organic light emitting element 410, at least one of deposition, etching, and ashing may be performed using the above-stated substrate treatment device.

Layers formed of metal, for example, gate electrodes 422 and 432, source electrodes 423 and 433, and drain electrodes 424 and 434 of the thin film transistors 420 and 430, the first capacitor plate 441 and the second capacitor plate 442 of the capacitor 440, and the pixel electrode 411 and the common electrode 413 of the organic light emitting element 410 may be formed through deposition of a metal layer and patterning of the deposited metal layer. The organic emission layer 412 of the organic light emitting element 410 may be formed through spin-coating of the metal layer and patterning of the spin-coated metal layer.

By way of summation and review, an inductively coupled plasma treatment device may include a dielectric material, a support supporting the dielectric material, an antenna disposed on the dielectric material, and a high frequency power source connected with the antenna. The inductively coupled plasma treatment device may have a simple structure and may generate a plasma having relatively high density at a lower pressure of several millitorr (mTorr).

As the size of display substrates increases, it becomes desirable to provide a substrate treatment device that is also increased in size. In a typical substrate treatment device, a dielectric material may be damaged due to the weight of the dielectric material and the stress concentration in a vacuum state. Therefore, the dielectric material may be stably supported by increasing the size and thickness of a support. However, a support made of aluminum or stainless steel may shield an electromagnetic field induced from the antenna, thereby causing a power loss.

In a substrate treatment device for processing a large-sized substrate according to the present embodiments, a rib structure is formed as a three-dimensional structure bent in at least one direction to stably support dielectric materials. Accordingly, a stability in shape may be improved, and the width of the rib structure may be reduced to suppress a shielding of an electromagnetic field induced from the antenna. Thus, a power loss due to the rib structure can be minimized and process efficiency of the substrate can be improved. Further, a large-sized OLED display can be easily manufactured using the above-stated substrate treatment device.

The above-stated substrate treatment device may be used as a deposition device for deposition of a metal layer by providing a metal deposition source (not shown). In addition, the substrate treatment device may be used as an etching device that eliminates a part of a metal layer and a part of a spin-coated organic emission layer by receiving an etching gas. Further, the substrate treatment device may be used an ashing device that eliminates a photoresist film used as a mask layer in a patterning process. With the above-stated substrate treatment device, the large-sized OLED display 400 can be easily manufactured.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims

What is claimed is:

1. A substrate treatment device, comprising:
a substrate processing chamber where a plasma treatment process is performed;
a rib structure provided in an upper portion of the substrate processing chamber, the rib structure having a form of a three-dimensional structure bent along at least one direction;
dielectric material structures, each having an edge fixed to the rib structure; and
an antenna provided in a portion of each of dielectric materials facing an exterior of the substrate treatment device, the antenna being connected with a high frequency power source and forming an inductive electromagnetic field in the substrate processing chamber through an inner space of each of the dielectric material structures.

2. The substrate treatment device of claim 1, wherein the rib structure includes first structures extending downwardly in a radial manner from a center apex and second structures disposed along a circumferential direction so as to cross the first structures.

3. The substrate treatment device of claim 2, wherein the first structures are equidistantly spaced apart at a lowest end of the rib structure, contacting the substrate processing chamber.

4. The substrate treatment device of claim 2, wherein:
the second structures are individually dimensioned according to a distance and curvature between respective first structures, and
ends of the second structures are coupled to the first structures.

5. The substrate treatment device of claim 2, wherein:
the first structures and the second structures each include base supports forming a basic frame and protrusion portions formed at a center of an external surface of the base support, and
the external surface of the base support and a side surface of the protrusion portion form a seating portion that supports an edge of one of the dielectric material structures.

6. The substrate treatment device of claim 1, wherein the rib structure includes third structures disposed in parallel with each other at a distance from each other and bent along one direction, and fourth structures disposed along a circumference direction so as to cross the third structures.

7. The substrate treatment device of claim 6, wherein the third structures are bent to the same direction, and one of the third structures disposed in the middle of the third structures has the greatest height.

8. The substrate treatment device of claim 6, wherein the fourth structures are individually dimensioned according to a distance and curvature between the third structures, and ends of the fourth structure are coupled to the third structures.

9. The structure treatment device of claim 6, wherein:
the third structures and the fourth structures each include base supports forming a basic frame and protrusion portions formed in a center of an external surface of the base support, and
the external surface of the base support and a side surface of the protrusion portion form a seating portion that supports an edge of one of the dielectric material structures.

10. The substrate treatment device of claim 7, wherein the rib structure further includes a center structure bent along a direction crossing the third structures.

11. The substrate treatment device of claim 1, wherein the rib structure includes fifth structures disposed in parallel with each other at a distance from each other and bent along one direction, and sixth structures disposed in a straight line and crossing the fifth structures.

12. The substrate treatment device of claim 11, wherein:
the fifth structures are bent to the same direction and have the same length, and
the sixth structures are separated from each other by a same distance along a length direction of the fifth structures.

13. The substrate treatment device of claim 11, wherein:
the sixth structures are individually dimensioned with a length corresponding to the distance between the fifth structures, and
ends of the sixth structure are coupled to the fifth structures.

14. The substrate treatment device of claim 11, wherein:
the fifth structures and the sixth structures each include base supports forming a basic frame and protrusion portions formed in a center of an external surface of the base support, and
the external surface of the base support and a side surface of the protrusion portion form a seating portion supporting an edge of one of the dielectric material structures.

15. The substrate treatment device of claim 1, wherein the dielectric material structures are each dimensioned to correspond to a size and curvature of a space partitioned by the rib structure.

16. The substrate treatment device of claim 15, wherein a gas inlet for injection of a reaction gas is disposed in one of the dielectric material structures.

17. A manufacturing method of an organic light emitting diode (OLED) display, the method comprising:
forming a driving circuit including a thin film transistor and a capacitor; and
forming an organic light emitting element electrically connected with the driving circuit,
wherein in at least one of the forming of the driving circuit and the forming of the organic light emitting element, at least one of deposition, etching, and ashing is performed using the substrate treatment device according to claim 1.
